(19) United States
(12) Patent Application Publication
(10) Pub. No.: US 2024/0242972 A1
(43) Pub. Date: Jul. 18, 2024

(54) SUBSTRATE PROCESSING METHOD AND SUBSTRATE PROCESSING APPARATUS

(71) Applicant: SCREEN Holdings Co., Ltd., Kyoto (JP)

(72) Inventors: Masaki INABA, Kyoto-shi, Kyoto (JP); Kei SUZUKI, Kyoto-shi, Kyoto (JP)

(21) Appl. No.: 18/562,072

(22) PCT Filed: Apr. 8, 2022
(86) PCT No.: PCT/JP2022/017352

§ 371 Date: Nov. 17, 2023

(30) Foreign Application Priority Data
Jun. 7, 2021 (JP) 2021-095025

(51) Int. Cl. H01L 21/311; H01L 21/67

(52) U.S. Cl. CPC H01L 21/31138; H01L 21/67069; H01L 21/67103

(57) ABSTRACT

A substrate processing method includes the steps of: a) placing a substrate having an organic film, on a placement surface of a substrate placing unit, such that the substrate is covered with a lid with a space interposed between the lid and the substrate; b) heating the lid to a second temperature higher than a first temperature while heating the placement surface of the substrate placing unit on which the substrate is placed, to the first temperature; and c) introducing a gas containing ozone into the space through the through-hole of the lid while performing the step of b).

### TECHNICAL FIELD

The present invention relates to a method and apparatus for processing a substrate. Examples of the substrate that is a processing target include a semiconductor wafer, a substrate for a flat panel display (FPD) such as a liquid crystal display apparatus or an organic electroluminescence (EL) display apparatus, a substrate for an optical disc, a substrate for a magnetic disk, a substrate for a magneto-optical disc, a substrate for a photomask, a ceramic substrate, and a substrate for a solar cell.

### BACKGROUND ART

A step of manufacturing a semiconductor device often includes a step of irradiating a semiconductor substrate (typically a silicon wafer) with ions. The ion irradiating step is, for example, an ion implanting step for introducing impurity ions into the semiconductor substrate or an ion etching step for forming a pattern. In these steps, irradiation with ions is performed using a resist formed as a mask in advance on a front surface of the semiconductor substrate. Consequently, the semiconductor substrate can be selectively irradiated with ions. The irradiation with ions is performed not only on the substrate but also on the resist used as a mask. Consequently, a surface layer of the resist is altered by carbonization or the like, and thereby a hardened film is formed. In particular, a strongly hardened film is formed on a front surface of a resist film into which a high dose of ions is implanted.

For example, according to Japanese Patent Application Laid-Open No. 2016-181677 (Patent Document 1), as a process for removing a resist having a hardened film from a front surface of a substrate, a high temperature SPM process performed by supplying a high-temperature sulfuric acid/hydrogen peroxide mixture (SPM) to the front surface of the substrate is known. However, since it is not possible to easily remove the hardened film, it is necessary to perform the high temperature SPM process for a long time. Therefore, consumption of an SPM increases. In particular, sulfuric acid as a constituent liquid of the SPM is a large environmental burden and is costly even though the sulfuric acid is neutralized, and thus it is desirable to reduce an amount of sulfuric acid used. In this respect, a method by which a resist film on which a hardened film is formed can be removed from a substrate with a reduction in amount of a treatment liquid containing sulfuric acid used is desired. As an ashing method applicable to this purpose, plasma processing or ozone processing is known. In particular, since the ozone processing can avoid ion impact associated with the plasma processing, a resist film (more generally, an organic film) can be removed while large damage to the substrate is avoided.

For example, an ashing method according to International Publication No. WO 2007/123197 (Patent Document 2) includes a substrate heating step of heating a treatment target object on a substrate accommodated in a treatment chamber to 180° C. or higher, a wet ozone gas heating step of heating a wet ozone gas containing a treatment liquid to 120° C. or higher, and a wet ozone gas supplying step of supplying the wet ozone gas heated in the wet ozone gas heating step to the treatment target object on the substrate. According to this publication, substantially the following effects are claimed. When the treatment liquid contained in the wet ozone gas adheres to the treatment target object heated to 180° C. or higher, the treatment target object is subjected to strong ashing (carbonizing). According to this publication, it is considered that this ashing is caused by strong oxidizing power of radicals formed when an ozone gas reaches a treatment target surface, and this oxidation reaction is promoted because the temperature of the treatment target object is a high temperature of 180° C. or higher.

### PRIOR ART DOCUMENTS

### Patent Documents

Patent Document 1: Patent Application Laid-Open No. 2016-181677
Patent Document 2: International Publication No. WO 2007/123197

### SUMMARY

### Problem to be Solved by the Invention

According to a technology described in International Publication No. WO 2007/123197, an ozone gas reaches a treatment target object heated to 180° C. or higher on a substrate, so that a strong oxidizing action of radicals is developed. At that time, since a temperature of the substrate is approximately the same as the temperature of the treatment target object, that is, the high temperature of 180° C. or higher, oxidation of the substrate is likely to proceed during ozone processing. The ozone processing here is usually intended to remove an organic film (typically a resist film) as the treatment target object and is not usually intended to oxidize the substrate. This unintended progress of oxidation may adversely affect a product obtained using the substrate. Specifically, a desired shape or a desired electrical characteristic may not be obtained. On the other hand, when a heating temperature is simply lowered in the technology, it becomes difficult to obtain practical treatment efficiency.

The present invention has been made to solve the above problems, and objects thereof are to provide a substrate processing method and a substrate processing apparatus capable of suppressing progress of oxidation of a substrate while efficiently removing an organic film from the substrate.

### Means to Solve the Problem

According to a first aspect, there is provided a substrate processing method for removing an organic film from a substrate by using a substrate processing apparatus including a substrate placing unit having a placement surface on which the substrate is placed, and a lid that covers the substrate placed on the placement surface with a space interposed between the lid and the substrate, has an inner surface facing the space and an outer surface opposite to the inner surface, and has a through-hole connecting the inner surface and the outer surface, the substrate processing method including the steps of: a) placing the substrate having the organic film on the placement surface of the substrate placing unit such that the substrate is covered with the lid with the space interposed between the lid and the substrate; b) heating the lid to a second temperature higher than a first temperature while heating the placement surface of the substrate placing unit on which the substrate is placed, to the first temperature; and c) introducing a gas containing ozone into the space through the through-hole of the lid while performing the step of b).

According to a second aspect, in the substrate processing method according to the first aspect, the first temperature is 150° C. or lower, and the second temperature is higher than 150° C. According to a third aspect, in the substrate processing method according to the second aspect, the first temperature is 100° C. or higher. According to a fourth aspect, in the substrate processing method according to the second or third aspect, the second temperature is 200° C. or lower.

According to a fifth aspect, there is provided a substrate processing apparatus for removing an organic film from a substrate, the substrate processing apparatus including: a substrate placing unit that has a placement surface on which the substrate is to be placed and is equipped with a first heater for heating the placement surface; a lid that covers the substrate placed on the placement surface of the substrate placing unit with a space interposed between the lid and the substrate, has an inner surface facing the space and an outer surface opposite to the inner surface, and has a through-hole connecting the inner surface and the outer surface; a second heater provided on the outer surface of the lid to heat the lid; a gas pipe that projects from the outer surface of the lid and supplies a gas to the through-hole of the lid; a gas supply unit that supplies a gas containing ozone to the gas pipe; and a controller that controls the first heater and the second heater. The controller controls the first heater so that the placement surface of the substrate placing unit on which the substrate is placed is heated to a first temperature and controls the second heater so that the lid is heated to a second temperature higher than the first temperature.

According to a sixth aspect, in the substrate processing apparatus according to the fifth aspect, a region having thermal conductivity lower than thermal conductivity of the gas pipe is interposed between the second heater and the gas pipe. According to a seventh aspect, in the substrate processing apparatus according to the sixth aspect, the region includes a gap. According to an eighth aspect, in the substrate processing apparatus according to the sixth or seventh aspect, the region includes a member having thermal conductivity lower than thermal conductivity of the gas pipe.

### Effects of the Invention

According to the above-described individual aspects, a gas containing ozone is introduced into the space through the through-hole of the lid while the substrate is heated at a first temperature and the lid is heated to a second temperature higher than the first temperature. Since the first temperature is lower than the second temperature, a temperature of the substrate is suppressed as compared with a case where the first temperature is equal to or higher than the second temperature. Consequently, it is possible to suppress progress of oxidation of the substrate when an organic film on the substrate is removed by a substrate processing method. In addition, since the second temperature is higher than the first temperature, a temperature of a gas in the space on the substrate becomes higher compared to a case where the second temperature is equal to or lower than the first temperature. Consequently, this promotes generation of radicals by thermal decomposition of ozone in the gas. Accordingly, the organic film on the substrate can be efficiently removed. Based on this, it is possible to suppress the progress of oxidation of the substrate while the organic film is efficiently removed from the substrate.

In a case where the first temperature is 150° C. or lower, the progress of oxidation of the substrate can be more sufficiently suppressed. In a case where the second temperature is higher than 150° C., the generation of radicals by the thermal decomposition of ozone in the gas is more sufficiently promoted.

In a case where the first temperature is 100° C. or higher, the temperature of the organic film is thereby increased. Consequently, the organic film can be more efficiently removed.

In a case where the second temperature is 200° C. or lower, it is possible to prevent a gas pipe for supplying a gas to a through-hole of the lid from being excessively heated by heat conduction from the lid. Consequently, thermal decomposition of ozone in an upstream part of the gas pipe is suppressed. Accordingly, it is possible to suppress a decrease in processing efficiency due to deactivation of radicals before the radicals reach the substrate.

In a case where a region having thermal conductivity lower than the thermal conductivity of the gas pipe is interposed between the second heater and the gas pipe, an increase in temperature of the gas pipe due to heat from the second heater is suppressed. Consequently, thermal decomposition of ozone in an upstream part of the gas pipe is suppressed. Accordingly, it is possible to suppress a decrease in processing efficiency due to deactivation of radicals before the radicals reach the substrate.

### BRIEF DESCRIPTION OF DRAWINGS

FIG. 1 is a plan view schematically showing a configuration of a substrate processing apparatus according to one embodiment.

FIG. 2 is a cross-sectional view schematically showing a configuration of a dry processing unit included in the substrate processing apparatus of FIG. 1.

FIG. 3 is a cross-sectional view more specifically showing a configuration of a thermal processing unit included in the dry processing unit of FIG. 2.

FIG. 4 is a cross-sectional view showing a modification example of FIG. 3.

FIG. 5 is a diagram schematically showing configurations of a supply system and an exhaust system of a gas with respect to the thermal processing unit of FIG. 3.

FIG. 6 is a cross-sectional view schematically showing a configuration of a wet processing unit included in the substrate processing apparatus of FIG. 1.

FIG. 7 is a block diagram schematically showing a configuration of a control apparatus included in the substrate processing apparatus.

FIG. 8 is a cross-sectional view schematically showing one step of a substrate processing method according to another embodiment.

FIG. 9 is a cross-sectional view schematically showing one step of the substrate processing method according to the other embodiment.

FIG. 10 is a cross-sectional view schematically showing one step of the substrate processing method according to the other embodiment.

FIG. 11 is a graph showing a theoretical relationship between a temperature of an ozone gas and a generation amount of oxygen radicals.

FIG. 12 is a graph showing an experimental result of a relationship between a substrate temperature and a removal rate of an organic film on a substrate when an unheated ozone gas is supplied onto the substrate.

FIG. 13 is a flowchart schematically showing the substrate processing method.

FIG. 14 is a flowchart schematically showing the substrate processing method.

FIG. 15 is a graph showing experimental results of a removal rate of an organic film in an example in which a lid is heated and a comparative example in which the lid is not heated.

### DESCRIPTION OF EMBODIMENTS

Hereinafter, embodiments of the present invention will be described in detail with reference to the accompanying drawings.

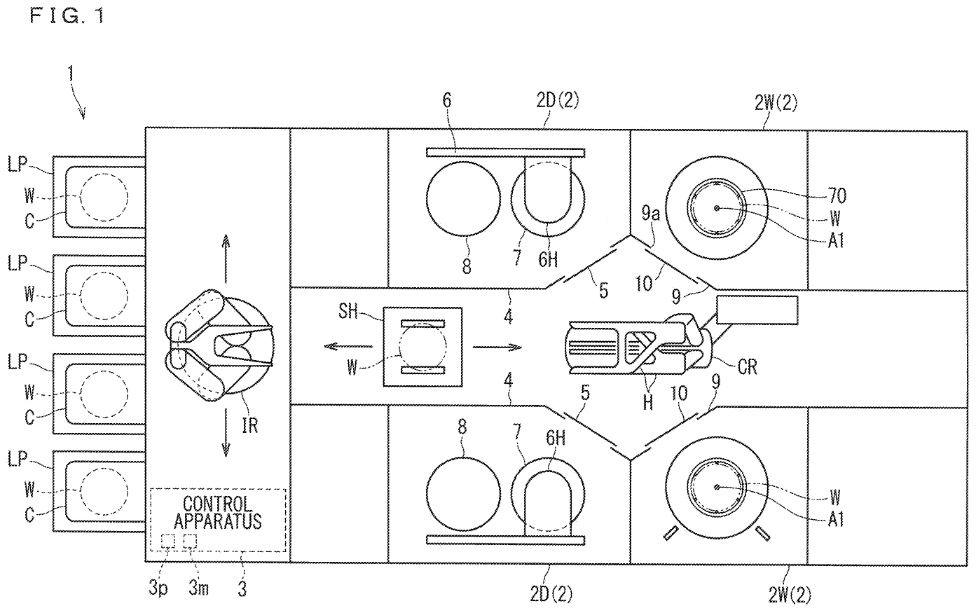

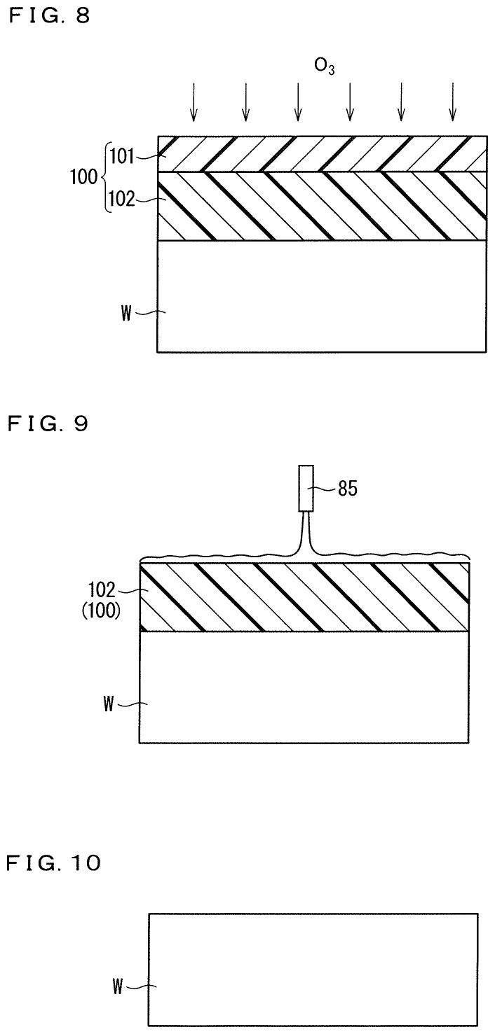

FIG. 1 is a schematic plan view showing a schematic configuration of a substrate processing apparatus according to one embodiment of the present invention. A substrate processing apparatus 1 is a single-wafer apparatus for performing substrate processing on substrates W one by one. With this substrate processing, an organic film (typically, a resist film 100 (FIG. 8) to be described below) is removed from the substrate W.

The substrate W is, for example, a semiconductor wafer or the like. The substrate processing apparatus 1 includes a plurality of load ports LP that hold a plurality of respective carriers C that accommodate the substrates W, and a plurality of processing units 2 that process the substrates W transported from the plurality of load ports LP with a processing fluid such as a processing liquid or a processing gas. The substrate processing apparatus 1 further includes a transport unit that transports the substrates W. The transport unit includes an indexer robot IR, a shuttle SH, and a center robot CR arranged on transport routes extending from the plurality of load ports LP to the plurality of processing units 2. The indexer robot IR transports the substrates W between the plurality of load ports LP and the shuttle SH. The shuttle SH shuttles between the indexer robot IR and the center robot CR to transport the substrates W. The center robot CR transports the substrates W between the shuttle SH and the plurality of processing units 2. The center robot CR further transports the substrates W between the plurality of processing units 2. The thick arrows shown in FIG. 1 indicate moving directions of the indexer robot IR and the shuttle SH.

The plurality of processing units 2 form four towers arranged at four horizontally separated positions, respectively. Each tower includes the plurality of processing units 2 stacked in an up-down direction. Two of the four towers are arranged on either side of the transport route. The plurality of processing units 2 include a plurality of dry processing units 2D that process the substrates W while the substrates W are dried and a plurality of wet processing units 2W that process the substrates W with a processing liquid. The two towers on the load ports LP side are formed of the plurality of dry processing units 2D, and the remaining two towers are formed of the plurality of wet processing units 2W.

The substrate processing apparatus 1 further includes a control apparatus 3 (controller) that controls the substrate processing apparatus 1. The control apparatus 3 is typically a computer and includes a memory 3m that stores information such as a program and a processor 3p that controls the substrate processing apparatus 1 in accordance with the information stored in the memory 3m.

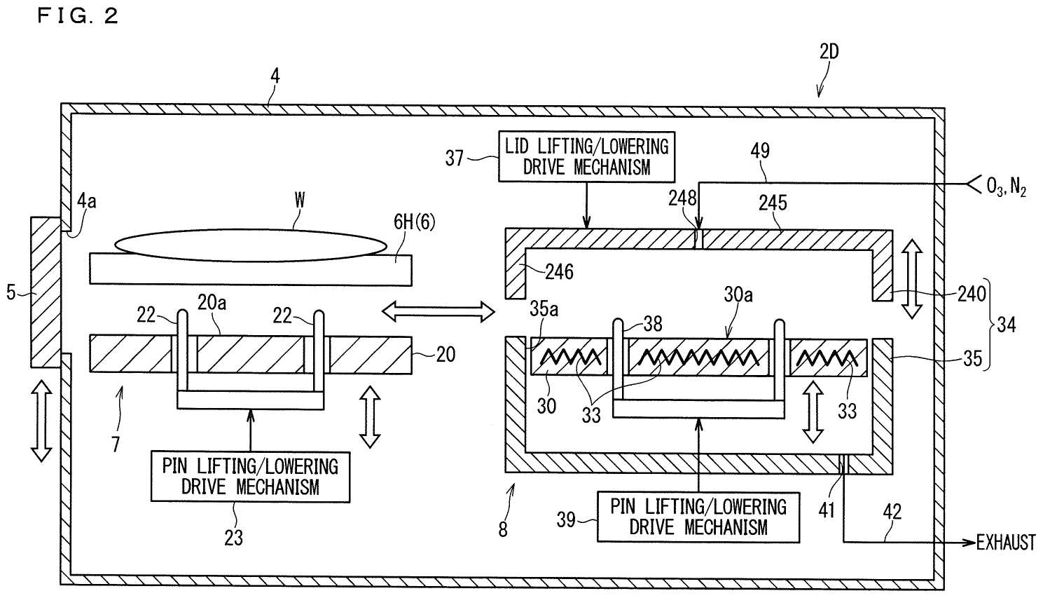

FIG. 2 is a schematic cross-sectional view for describing a configuration example of the dry processing units 2D. The dry processing unit 2D includes a dry chamber 4 having a loading/unloading port 4a through which the substrate W passes, a shutter 5 that opens and closes the loading/unloading port 4a of the dry chamber 4, a thermal processing unit 8 that supplies a processing gas to the substrate W while heating the substrate W in the dry chamber 4, a cooling unit 7 that cools, in the dry chamber 4, the substrate W heated by the thermal processing unit 8, and an in-chamber transport mechanism 6 that transports the substrate W in the dry chamber 4. The center robot CR (FIG. 1) takes the substrate W in and out of the dry chamber 4 through the loading/unloading port 4a. The cooling unit 7 is disposed in the dry chamber 4 near the loading/unloading port 4a.

The cooling unit 7 includes a cool plate 20, a lift pin 22 that is moved up and down by penetrating a cool plate 20, and a pin lifting/lowering drive mechanism 23 that moves the lift pin 22 up and down. The cool plate 20 has a cooling surface 20a on which the substrate W is placed. A refrigerant route (not shown) through which a refrigerant (typically cooling water) circulates is formed inside the cool plate 20. The lift pin 22 is moved up and down between an upper position where the lift pin supports the substrate W above the cooling surface 20a and a lower position where the tip is put below the cooling surface 20a.

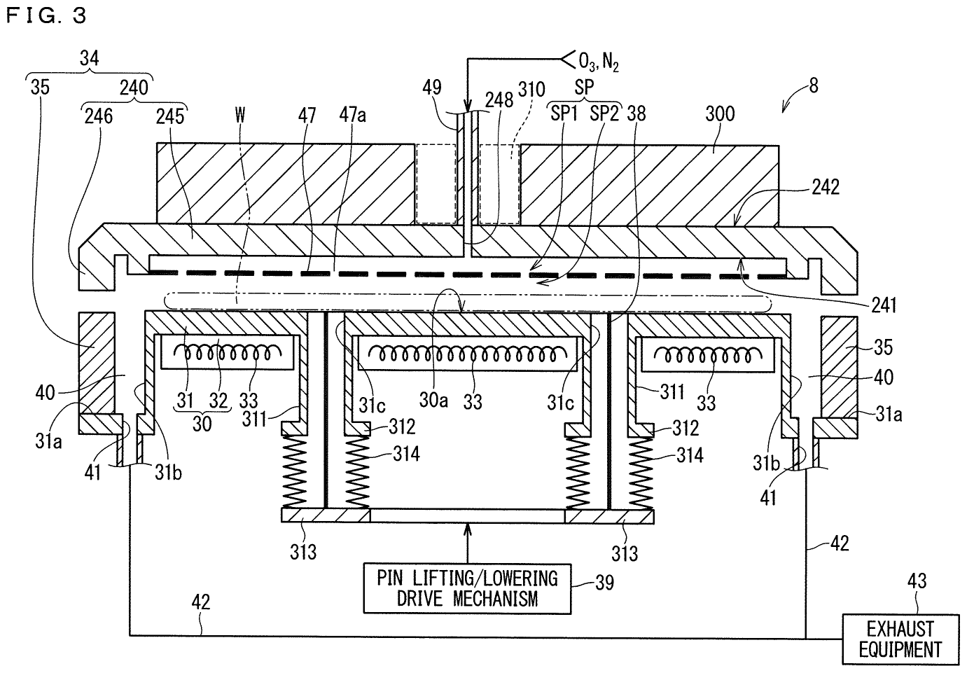

FIG. 3 is a cross-sectional view more specifically showing the thermal processing unit 8. With reference to FIGS. 2 and 3, the thermal processing unit 8 includes a hot plate 30 (substrate placing unit), a thermal processing chamber 34 that accommodates the hot plate 30, a lift pin 38 that is moved up and down by penetrating the hot plate 30, and a pin lifting/lowering drive mechanism 39 that moves the lift pin 38 up and down.

The hot plate 30 includes a faceplate 31 and an under plate 32 coupled to an undersurface of the faceplate 31. A top surface of the faceplate 31 is configured of a placement surface 30a on which the substrate W is to be placed. The placement surface 30a has a planar shape which corresponds to the shape of the substrate W and is slightly larger than the substrate W. Specifically, when the substrate W has a circular shape, the placement surface 30a is formed in a circular shape that is slightly larger than the substrate W.

The under plate 32 of the hot plate 30 is equipped with a first heater 33 for heating the placement surface 30a. The first heater 33 is configured to heat the substrate W placed on the placement surface 30a. For example, the first heater 33 may be configured to heat the substrate W to 150° C.

The faceplate 31 of the hot plate 30 has a step portion 31a around the placement surface 30a. The step portion 31a is an annular horizontal surface positioned below the placement surface 30a. A stepped surface 31b formed by a vertically cylindrical surface is formed between an inner circumferential edge of the step portion 31a and an outer circumferential edge of the placement surface 30a. A cylindrical chamber body 35 is disposed on a top surface of the step portion 31a. A cylindrical exhaust space 40 is formed between an inner wall surface of the chamber body 35 and the stepped surface 31b of the faceplate 31. Exhaust ports 41 penetrating the step portion 31a are formed at a bottom portion of the exhaust space 40. The exhaust ports 41 are preferably arranged at a plurality of positions (for example, three positions) at intervals in a circumferential direction. The exhaust port 41 is coupled to exhaust equipment 43 via an exhaust line 42.

A through-hole 31c is formed in the faceplate 31, and the lift pin 38 penetrates the through-hole 31c. A hollow shaft 311 into which the lift pin 38 is inserted is coupled to the undersurface of the faceplate 31. A flange 312 is formed at a lower end of the hollow shaft 311, and the flange 312 faces a support plate 313 coupled to the lower end of the lift pin 38. The support plate 313 is coupled to the pin lifting/lowering drive mechanism 39 and is moved up and down by the pin lifting/lowering drive mechanism 39. A bellows 314 surrounding the lift pin 38 is disposed between the support plate 313 and the flange 312. The bellows 314 expands and contracts in accordance with the up-down movement of the support plate 313 and maintains airtightness of a space in the thermal processing chamber 34.

The thermal processing chamber 34 includes a chamber body 35 and a lid 240 that moves up and down above the chamber body 35. The thermal processing unit 8 includes a lid lifting/lowering drive mechanism 37 that lifts and lowers the lid 240. The chamber body 35 has an opening 35a open upward, and the lid 240 opens and closes the opening 35a. The lid 240 is moved up and down between a closed position (lower position) where the lid closes the opening 35a of the chamber body 35 to form a sealed processing space therein and an upper position where the lid is retracted upward to open the opening 35a. The lift pin 38 is moved up and down between an upper position where the lift pin supports the substrate W above the placement surface 30a and a lower position where a tip is put below the placement surface 30a.

The lid 240 has an inner surface 241 facing an inner side of the thermal processing chamber 34 and an outer surface 242 facing an outer side of the thermal processing chamber 34. The lid 240 includes a plate portion 245 extending in parallel with the placement surface 30a and a cylindrical portion 246 extending downward from a circumferential edge of the plate portion 245. Specifically, the plate portion 245 is substantially circular, and accordingly, the cylindrical portion 246 has a cylindrical shape. A lower end of the cylindrical portion 246 faces an upper end of the chamber body 35. Consequently, the opening 35a of the chamber body 35 can be opened and closed by the up-down movement of the lid 240.

A straightening plate 47 is disposed inside the cylindrical portion 246. The straightening plate 47 is typically a shower plate in which a large number of through-holes 47a are formed by punching to be dispersed. The straightening plate 47 is made of, for example, stainless steel. The straightening plate 47 is disposed in parallel with the placement surface 30a with a space SP1 below an undersurface of the plate portion 245. The undersurface of the plate portion 245 is parallel to the placement surface 30a of the hot plate 30, and accordingly, the straightening plate 47 is parallel to the placement surface 30a of the hot plate 30. The straightening plate 47 is fixed to the plate portion 245 to be positioned above the lower end of the cylindrical portion 246. Hence, when the lid 240 is in the closed position (lower position), a space SP2 is formed between the straightening plate 47 and the placement surface 30a. More specifically, when the substrate W is placed on the placement surface 30a, and the lid 240 is at the closed position (lower position), the straightening plate 47 is located above the top surface of the substrate W, and thus the space SP2 is formed between the substrate W and the straightening plate 47. Accordingly, a space SP including the space SP1 and the space SP2 is formed between the plate portion 245 of the lid 240 and the substrate W placed on the placement surface 30a of the hot plate 30, and the inner surface 241 of the lid 240 faces the space SP. The plate portion 245 of the lid 240 covers the substrate W placed on the placement surface 30a of the hot plate 30, with the space SP therebetween.

The lid 240 has a through-hole 248 connecting the inner surface 241 and the outer surface 242. In the present embodiment, the through-hole 248 penetrates a central portion of the plate portion 245. The through-hole 248 is connected to a gas pipe 49 for supplying a gas to the through-hole 248. The gas pipe 49 is made of, for example, stainless steel. The gas pipe 49 projects from the outer surface 242 of the lid 240 over the through-hole 248. The gas introduced from the through-hole 248 into the thermal processing chamber 34 passes through the straightening plate 47 and is supplied to a processing space below the straightening plate 47. Hence, the gas is supplied to the substrate W placed in the processing space. By the function of the straightening plate 47, the gas is evenly distributed and supplied toward substantially the entire region of the placement surface 30a (hence, substantially the entire region of the top surface of the substrate W).

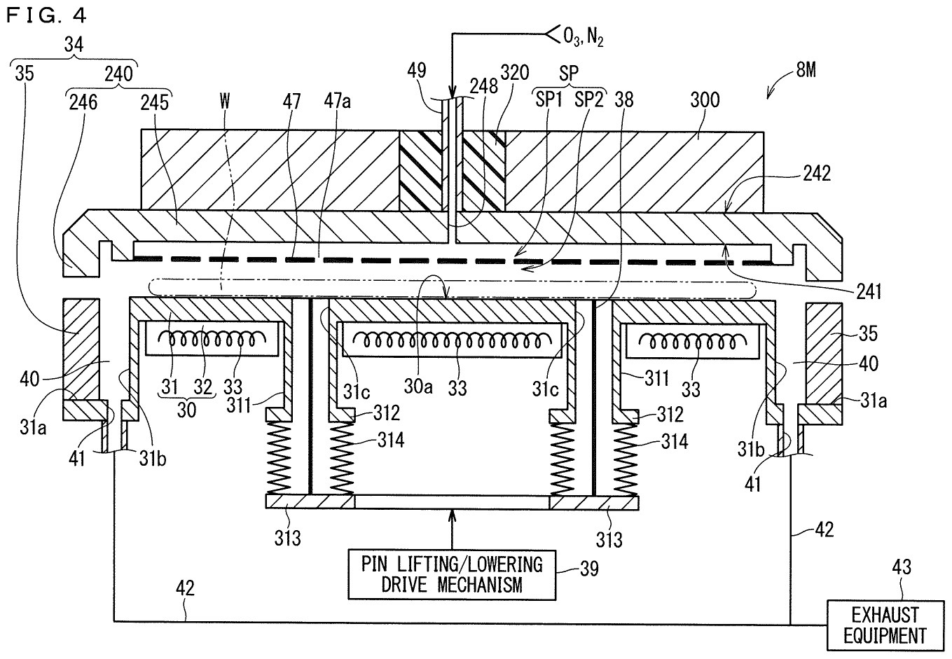

The thermal processing unit 8 includes a second heater 300. The second heater 300 is provided to heat the lid 240 and is provided on the outer surface 242 of the lid 240. A region having lower thermal conductivity than that of the gas pipe 49 is preferably interposed between the second heater 300 and the gas pipe 49. This region is a gap 310 in the thermal processing unit 8 (FIG. 3). Note that the region is not limited to the gap 310. For example, in a thermal processing unit 8M of a modification example shown in FIG. 4, the region is a heat insulating member 320 having lower thermal conductivity than that of the gas pipe 49. The heat insulating member 320 may be made of a resin such as polytetrafluoroethylene (PTFE). As another modification example (not shown), the region may include both the gap described above and the heat insulating member described above.

The in-chamber transport mechanism 6 (FIG. 2) transports the substrate W inside the dry chamber 4. More specifically, the in-chamber transport mechanism 6 includes an in-chamber transport hand 6H that transports the substrate W between the cooling unit 7 and the thermal processing unit 8. The in-chamber transport hand 6H is configured to deliver the substrate W to and from the lift pins 22 of the cooling unit 7 and deliver the substrate W to and from the lift pins 38 of the thermal processing unit 8. Consequently, the in-chamber transport hand 6H can operate to receive the substrate W from the lift pin 22 of the cooling unit 7 and transfer the substrate W to the lift pin 38 of the thermal processing unit 8. Further, the in-chamber transport hand 6H can operate to receive the substrate W from the lift pins 38 of the thermal processing unit 8 and transfer the substrate W to the lift pins 22 of the cooling unit 7.

The typical operation of the dry processing unit 2D (FIG. 1) is generally as follows.

When the center robot CR loads the substrate W into the dry chamber 4, the shutter 5 is controlled to an opening position at which the loading/unloading port 4a (FIG. 2) is opened. In this state, a hand H of the center robot CR enters the dry chamber 4, and the substrate W is disposed above the cool plate 20. In this case, the lift pins 22 are lifted to the upper position and receives the substrate W from the hand H of the center robot CR. Thereafter, the hand H of the center robot CR retracts to the outside of the dry chamber 4. Next, the in-chamber transport hand 6H of the in-chamber transport mechanism 6 receives the substrate W from the lift pins 22 and transports the substrate W to the lift pins 38 of the thermal processing unit 8. At this time, the lid 240 is at the opening position (upper position), and the lift pins 38 support the received substrate W at the upper position. After the in-chamber transport hand 6H retracts from the thermal processing chamber 34, the lift pins 38 are lowered to the lower position to place the substrate W on the placement surface 30a. On the other hand, the lid 240 is lowered to the closed position (lower position) to form a sealed processing space enclosing the hot plate 30. In this state, thermal processing is performed on the substrate W.

When the thermal processing is completed, the lid 240 is lifted to the opening position (upper position), and the thermal processing chamber 34 is opened. Further, the lift pins 38 are lifted to the upper position to push up the substrate W to above the placement surface 30a. In this state, the in-chamber transport hand 6H of the in-chamber transport mechanism 6 receives the substrate W from the lift pins 38 and transports the substrate W to the lift pins 22 of the cooling unit 7. The lift pins 22 support the received substrate W at the upper position. After the in-chamber transport hand 6H retracts, the lift pins 22 are lowered to the lower position, and thereby the substrate W is placed on the cooling surface 20a of the cool plate 20. Consequently, the substrate W is cooled.

When the cooling of the substrate W is finished, the lift pins 22 are lifted to the upper position, thereby, pushing up the substrate W above the cooling surface 20a. In this state, the shutter 5 is opened, and the hand H of the center robot CR (FIG. 1) enters the dry chamber 4 and is disposed below the substrate W supported by the lift pins 22 (FIG. 2) at the upper position. In this state, when the lift pins 22 are lowered, the substrate W is passed to the hand H of the center robot CR. The hand H holding the substrate W retracts to the outside of the dry chamber 4, and then the shutter 5 closes the loading/unloading port 4a (FIG. 2).

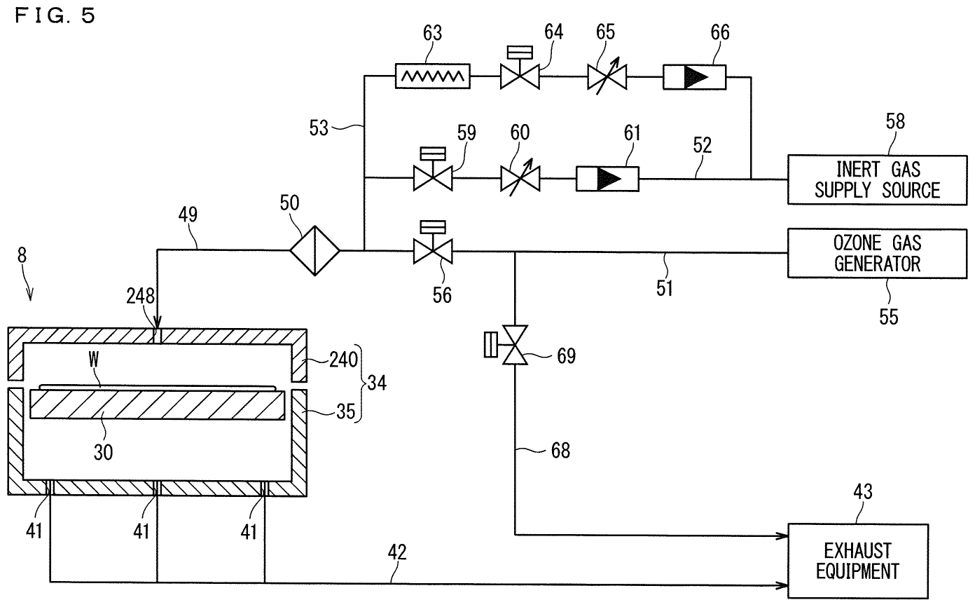

FIG. 5 is a system diagram for describing a configuration example of a supply system and an exhaust system of a gas with respect to the thermal processing unit 8.

An ozone gas supply line 51, a room-temperature inert gas supply line 52, and a high-temperature inert gas supply line 53 are coupled to the gas pipe 49 connected to the through-hole 248. A filter 50 for filtering foreign substances in a flowing gas is installed in the gas pipe 49.

The ozone gas supply line 51 is coupled to the ozone gas generator 55 (gas supply unit). The ozone gas generator 55 generates ozone and supplies a gas (hereinafter, also referred to as the ozone gas) containing the ozone to the gas pipe 49 via the ozone gas supply line 51. A temperature of the ozone gas at the time of being supplied to the gas pipe 49 is lower than 150° C., preferably lower than 100° C., and is typically about room temperature. In the ozone gas supply line 51, an ozone gas valve 56 that opens and closes a flow channel thereof is installed. Each of the ozone gas supply line 51 and the ozone gas valve 56 is an example of an ozone gas supply unit.

The room-temperature inert gas supply line 52 supplies a room-temperature inert gas supplied from an inert gas supply source 58. The inert gas is a chemically inert gas such as a nitrogen gas or an argon gas. The room-temperature inert gas supply line 52 supplies the inert gas supplied from the inert gas supply source 58 to the gas pipe 49 without heating the inert gas. In the room-temperature inert gas supply line 52, a room-temperature inert gas valve 59 that opens and closes a flow channel thereof, a flow regulating valve 60 that regulates a flow rate, and a flowmeter 61 are installed. Each of the room-temperature inert gas supply line 52, the room-temperature inert gas valve 59, and the like is an example of the room-temperature inert gas supply unit.

The high-temperature inert gas supply line 53 supplies an inert gas having a temperature higher than room temperature. Specifically, the high-temperature inert gas supply line 53 heats and supplies the room-temperature inert gas supplied from the inert gas supply source 58. More specifically, a heater 63 is installed in the high-temperature inert gas supply line 53. The heater 63 heats the inert gas flowing through the high-temperature inert gas supply line 53 to a high temperature of 150° C. or higher. More specifically, the heater 63 heats the inert gas flowing through the high-temperature inert gas supply line 53 so that the processing space in the thermal processing chamber 34 can be filled with the inert gas having a temperature of 150° C. or higher. In the high-temperature inert gas supply line 53, a high-temperature inert gas valve 64 that opens and closes a flow channel thereof, a flow regulating valve 65 that adjusts a flow rate, and a flowmeter 66 are installed upstream of the heater 63. Each of the high-temperature inert gas supply line 53, the heater 63, the high-temperature inert gas valve 64, and the like are an example of the high-temperature inert gas supply unit.

The exhaust line 42 is connected to the exhaust port 41 of the thermal processing chamber 34. The exhaust line 42 is connected to the exhaust equipment 43. Exhaust from the exhaust line 42 mainly prevents the ozone gas from flowing out of the thermal processing chamber 34. An ozone exhaust line 68 is connected to the ozone gas supply line 51 at a position upstream of the ozone gas valve 56. The ozone exhaust line 68 is connected to the exhaust equipment 43. An ozone exhaust valve 69 is installed in the ozone exhaust line 68. The ozone exhaust valve 69 is opened when the ozone gas remaining in the ozone gas supply line 51 is exhausted after the operation of the ozone gas generator 55 is stopped.

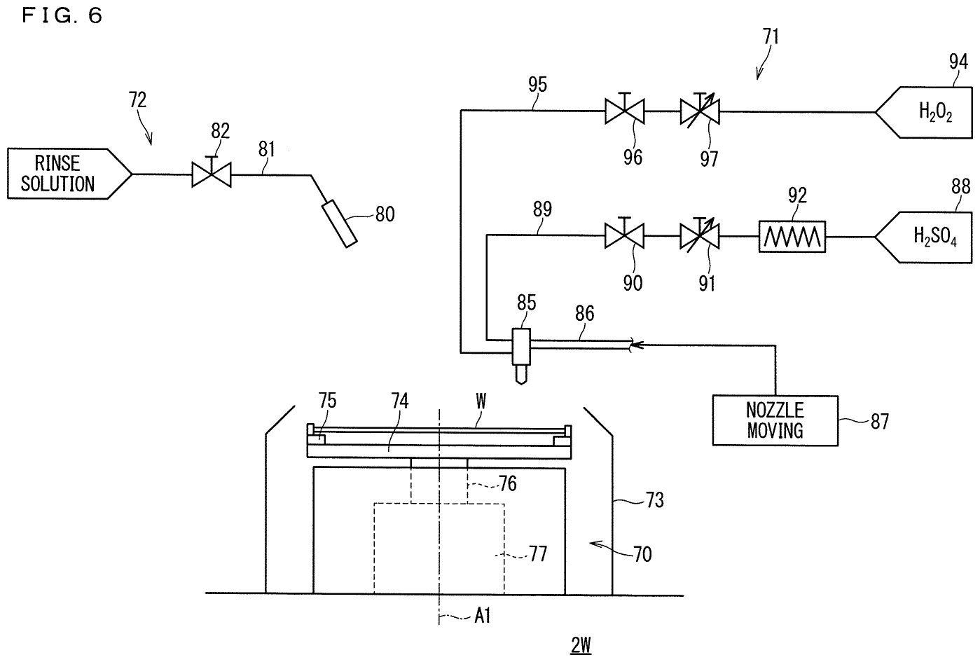

With reference to FIG. 6, the wet processing units 2W are single-wafer liquid processing units that process the substrates W one by one. The wet processing unit 2W includes a box-shaped wet chamber 9 (FIG. 1) that partitions an internal space, a spin chuck 70 (substrate holding means) that holds one substrate W in a horizontal posture in the wet chamber 9 and rotates the substrate W around a vertical rotation axis A1 passing through the center of the substrate W, an SPM supply unit 71 that supplies a processing liquid (in this embodiment, a sulfuric acid/hydrogen peroxide mixture (SPM)) containing sulfuric acid to the substrate W held by the spin chuck 70, a rinse solution supply unit 72, and a cylindrical cup 73 surrounding the spin chuck 70. As shown in FIG. 1, the wet chamber 9 has a loading/unloading port 9a through which the substrate W passes and has a shutter 10 for opening and closing the loading/unloading port 9a. The wet chamber 9 is an example of a liquid processing chamber in which substrate processing using a processing liquid is performed.

The spin chuck 70 includes a disk-shaped spin base 74 held in a horizontal posture, a plurality of chuck pins 75 that hold the substrate W in a horizontal posture above the spin base 74, a rotation shaft 76 extending downward from a central portion of the spin base 74, and a spin motor 77 that rotates the rotation shaft 76 to rotate the substrate W and the spin base 74 around the rotation axis A1. The spin chuck 70 is not limited to a pinching chuck that brings the plurality of chuck pins 75 into contact with a circumferential end surface of the substrate W and may be a vacuum chuck that holds the substrate W horizontally by causing a back surface (undersurface) of the substrate W, which is a non-device forming surface, to be suctioned to a top surface of the spin base 74.

The cup 73 is disposed outside (in a direction away from the rotation axis A1) the substrate W held by the spin chuck 70. The cup 73 surrounds the periphery of the spin base 74. The cup 73 receives the processing liquid discharged to the periphery of the substrate W when the processing liquid is supplied to the substrate W in a state where the spin chuck 70 rotates the substrate W. The processing liquid received by the cup 73 is sent to a collection apparatus or a drainage apparatus (not shown).

The rinse solution supply unit 72 includes a rinse solution nozzle 80 that ejects a rinse solution toward the substrate W held by the spin chuck 70, a rinse solution pipe 81 through which the rinse solution is supplied to the rinse solution nozzle 80, and a rinse solution valve 82 that switches between supply and supply stop of the rinse solution from the rinse solution pipe 81 to the rinse solution nozzle 80. The rinse solution nozzle 80 may be a fixed nozzle through which the rinse solution is ejected in a state where an ejection port of the rinse solution nozzle 80 is stationary. The rinse solution supply unit 72 may include a rinse solution nozzle moving unit that moves a solution landing position of the rinse solution with respect to the top surface of the substrate W by moving the rinse solution nozzle 80. When the rinse solution valve 82 is opened, the rinse solution supplied from the rinse solution pipe 81 to the rinse solution nozzle 80 is ejected from the rinse solution nozzle 80 toward a central portion of the top surface of the substrate W. The rinse solution is, for example, pure water (deionized water). The rinse solution is not limited to pure water and may be any one of carbonated water, electrolyzed ion water, hydrogen water, ozone water, and hydrochloric acid water having a dilute concentration (for example, about 10 ppm to 100 ppm). A temperature of the rinse solution may be room temperature or a temperature higher than room temperature (for example, 70° C. to) 90° C.).

The SPM supply unit 71 includes an SPM nozzle 85 through which an SPM is ejected toward the top surface of the substrate W, a nozzle arm 86 having a tip portion to which the SPM nozzle 85 is attached, and a nozzle moving unit 87 that moves the SPM nozzle 85 by moving the nozzle arm 86. The SPM nozzle 85 is, for example, a straight nozzle through which the SPM is ejected in a continuous flow state and is attached to the nozzle arm 86, for example, in a vertical posture in which the processing liquid is ejected in a direction perpendicular to the top surface of the substrate W. The nozzle arm 86 extends in a horizontal direction and is provided to be turnable about a swinging axis (not shown) extending in a perpendicular direction around the spin chuck 70.

The nozzle moving unit 87 horizontally moves the SPM nozzle 85 along a track passing through a central portion of the top surface of the substrate W in plan view by turning the nozzle arm 86 about the swinging axis. The nozzle moving unit 87 horizontally moves the SPM nozzle 85 between a processing position where the SPM ejected from the SPM nozzle 85 lands on the top surface of the substrate W and a home position where the SPM nozzle 85 is located around the spin chuck 70 in plan view. The processing position includes a central position where the SPM ejected from the SPM nozzle 85 lands at the central portion of the top surface of the substrate W and a circumferential position where the SPM ejected from the SPM nozzle 85 lands at a circumferential edge portion of the top surface of the substrate W.

The SPM supply unit 71 includes a sulfuric acid pipe 89 which is connected to the SPM nozzle 85 and to which sulfuric acid (H₂SO₄) is supplied from a sulfuric acid supply source 88 and a hydrogen peroxide solution pipe 95 which is connected to the SPM nozzle 85 and to which a hydrogen peroxide solution (H₂O₂) is supplied from a hydrogen peroxide solution supply source 94. Both the sulfuric acid supplied from the sulfuric acid supply source 88 and the hydrogen peroxide solution supplied from the hydrogen peroxide solution supply source 94 are aqueous solutions. The concentration of sulfuric acid is, for example, 90% to 98%, and the concentration of the hydrogen peroxide solution is, for example, 30% to 50%.

In the sulfuric acid pipe 89, a sulfuric acid valve 90 the opens and closes a flow channel of the sulfuric acid pipe 89, a sulfuric acid flow regulating valve 91 that changes a flow rate of sulfuric acid, and a heater 92 that heats sulfuric acid are installed in this order from the SPM nozzle 85 side. The heater 92 heats the sulfuric acid to a temperature (constant temperature within a range of 70° C. to 190° C., for example, 90° C.) higher than room temperature. In the hydrogen peroxide solution pipe 95, a hydrogen peroxide solution valve 96 that opens and closes a flow path of the hydrogen peroxide solution pipe 95 and a hydrogen peroxide solution flow regulating valve 97 that changes a flow rate of the hydrogen peroxide solution are installed in this order from the SPM nozzle 85 side. A room-temperature hydrogen peroxide solution (for example, about 23° C.) whose temperature is not adjusted is supplied to the hydrogen peroxide solution valve 96 through the hydrogen peroxide solution pipe 95.

The SPM nozzle 85 has, for example, a substantially cylindrical casing. A mixing chamber is formed inside the casing. The sulfuric acid pipe 89 is connected to a sulfuric acid introducing port disposed on a side wall of the casing of the SPM nozzle 85. The hydrogen peroxide solution pipe 95 is connected to a hydrogen peroxide solution introducing port disposed on a side wall of the casing of the SPM nozzle 85.

When the sulfuric acid valve 90 and the hydrogen peroxide solution valve 96 are opened, sulfuric acid (high-temperature sulfuric acid) from the sulfuric acid pipe 89 is supplied from the sulfuric acid introducing port of the SPM nozzle 85 to the mixing chamber inside the SPM nozzle, and the hydrogen peroxide solution from the hydrogen peroxide solution pipe 95 is supplied from the hydrogen peroxide solution introducing port of the SPM nozzle 85 to the mixing chamber inside the SPM nozzle. The sulfuric acid and the hydrogen peroxide solution flowing into the mixing chamber of the SPM nozzle 85 are sufficiently agitated and mixed in the mixing chamber. By this mixing, the sulfuric acid and the hydrogen peroxide solution are uniformly mixed, and a sulfuric acid/hydrogen peroxide mixture (SPM) is generated by reactions thereof. The SPM is a peroxymonosulfuric acid (H₂SO₅) having strong oxidizing power. Since the sulfuric acid heated to a high temperature is supplied, and mixing of the sulfuric acid and the hydrogen peroxide solution is an exothermic reaction, a high-temperature SPM is generated. Specifically, the SPM having a temperature (100° C. or higher, for example, 160° C.) higher than any temperature of the sulfuric acid and the hydrogen peroxide solution before mixing is generated. The high-temperature SPM generated in the mixing chamber of the SPM nozzle 85 is ejected toward the substrate W from an ejection port opened at the tip (lower end) of the casing.

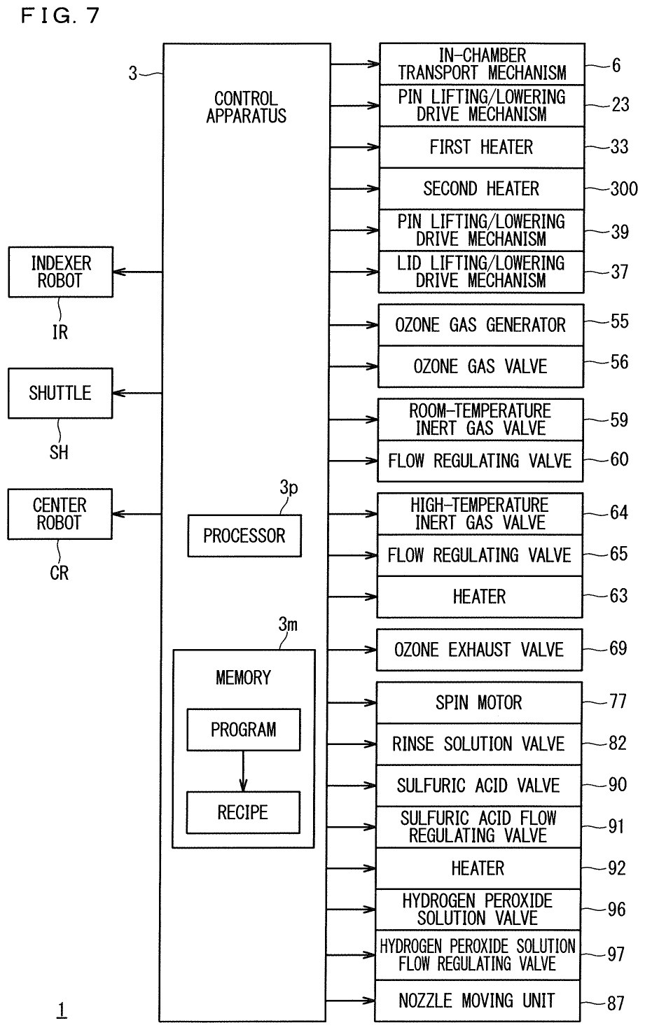

FIG. 7 is a block diagram for describing a configuration example related to control of the substrate processing apparatus 1. The control apparatus 3 is configured of, for example, a microcomputer. The control apparatus 3 includes the memory 3m that stores information such as a program and the processor 3p (CPU) that controls the substrate processing apparatus 1 in accordance with the information stored in the memory 3m. A recipe indicating a processing procedure and processing steps of the substrate W is stored in the memory 3m. The control apparatus 3 is programmed to execute processing on the substrate W by controlling the substrate processing apparatus 1 based on the recipe stored in the memory 3m. Specific control targets of the control apparatus 3 include the indexer robot IR, the shuttle SH, the center robot CR, the in-chamber transport mechanism 6, the pin lifting/lowering drive mechanisms 23 and 39, the first heater 33, the second heater 300, the lid lifting/lowering drive mechanism 37, the ozone gas generator 55, the ozone gas valve 56, the room-temperature inert gas valve 59, the flow regulating valve 60, the heater 63, the high-temperature inert gas valve 64, the flow regulating valve 65, the ozone exhaust valve 69, the spin motor 77, the rinse solution valve 82, the nozzle moving unit 87, the sulfuric acid valve 90, the sulfuric acid flow regulating valve 91, the heater 92, the hydrogen peroxide solution valve 96, the hydrogen peroxide solution flow regulating valve 97, and the like.

FIGS. 8 to 10 illustrate a typical example of the substrate processing performed by the substrate processing apparatus 1. The substrate W that is a processing target is, for example, a silicon substrate (silicon wafer). A resist film 100 (organic film) is formed on a front surface of the substrate W. The resist film 100 is used as a mask for selective ion implantation into the substrate W. In particular, a hardened film 101 is formed on a surface layer portion of the resist film 100 on the substrate W after ion implantation processing is performed with a high dose. The hardened film 101 is formed by alteration such as carbonization of the resist film 100. An unhardened resist film 102 (hereinafter, referred to as a “non-hardened film 102”) is present on a lower side of the hardened film 101 (the front surface side of the substrate W). Here, the substrate processing, that is, resist peeling processing or resist removal processing, for peeling off or removing the resist film 100 having the hardened film 101 on the surface layer portion from the front surface of the substrate W will be described. This processing includes ozone processing (FIG. 8) and also includes SPM processing (FIG. 9) after the ozone processing in the present example.

The ozone processing (see FIG. 8) is processing of supplying an ozone gas to the front surface of the substrate W (more specifically, the hardened film 101 of the resist film 100). In this processing, at least a part of ozone is decomposed into oxygen and oxygen radicals, and thereby the oxygen radicals and the hardened film 101 react with each other on the substrate W. As a result, the hardened film 101 volatilizes into the atmosphere. Consequently, the hardened film 101 is removed. That is, the ozone processing is hardened film removal processing for removing the hardened film 101 of the resist film 100. The ozone processing causes the hardened film 101 to be at least partially removed and preferably removed entirely.

The SPM processing (see FIG. 9) is executed after the ozone processing (hardened film removal processing). The SPM processing is liquid processing of supplying the SPM to the front surface of the substrate W (the front surface on which the resist film 100 is formed). The SPM has a function of removing the hardened film 101 and the non-hardened film 102 of the resist film 100, but a hardened film removal rate is much lower than a non-hardened film removal rate. Hence, when there is no hardened film 101 on the front surface of the resist film 100, the resist film 100 (non-hardened film 102) on the front surface of the substrate W can be quickly removed by supplying the SPM (FIG. 10). Even if the hardened film 101 slightly remains on the front surface of the resist film 100, the slight removal of the hardened film 101 can be achieved by the SPM processing in a short time, so that the resist film 100 can also be removed in a short time. Further, even if the hardened film 101 remains on the front surface of the resist film 100, the SPM infiltrates into the non-hardened film 102 and removes the non-hardened film 102, if there is an exposed portion of the non-hardened film 102, that is, if there is a liquid path that penetrates the hardened film 101 and reaches the non-hardened film 102. Consequently, since the hardened film 101 is lifted off together with the non-hardened film 102, the entire resist film 100 can be removed from the front surface of the substrate W by the SPM processing for a short time.

As described above, by performing the SPM processing (FIG. 9) after removing the hardened film 101 by the ozone processing (FIG. 8), the resist film 100 can be quickly removed from the front surface of the substrate W as compared with a case where the SPM processing is performed without performing the ozone processing (FIG. 10).

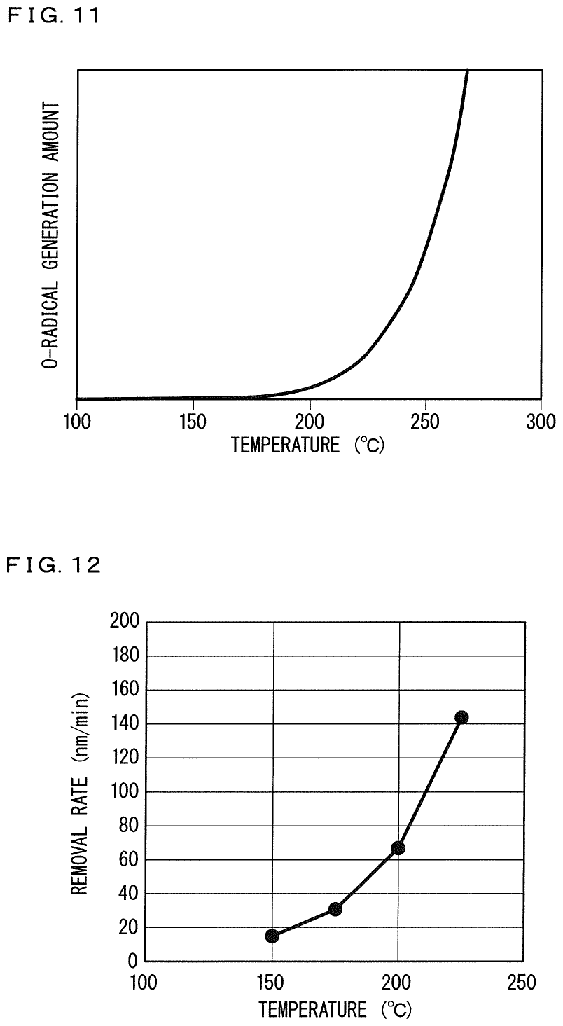

FIG. 11 is a graph for describing thermal decomposition of an ozone gas. Ozone (O₃) is known to cause thermal decomposition and generate oxygen radicals (O radicals) by imparting energy equal to or higher than active energy. As the temperature increases, a decomposition rate (chemical reaction rate constant k1) increases. From FIG. 11, it is found that a temperature of the ozone gas needs to be 150° C. or higher in order to sufficiently promote the thermal decomposition for generating oxygen radicals by satisfying a condition of the chemical reaction rate constant k1>0.

Moreover, the thermal decomposition of the ozone gas can be used not only for the purpose for generating oxygen radicals necessary for the ozone processing but also for the purpose for detoxifying the ozone gas. That is, when the ozone gas remains in the thermal processing chamber 34 after the ozone processing, the ozone gas is left at 150° C. or higher, and thereby the thermal decomposition of the ozone gas proceeds. The oxygen radicals generated at this time have a short life and are rapidly changed to oxygen. Accordingly, the ozone gas is quickly detoxified.

FIG. 12 is a graph showing an experimental result of a relationship between a substrate temperature and a removal rate of the resist film (organic film) on the substrate W when an unheated ozone gas is supplied onto the substrate W. From this result, it can be found that the removal rate remarkably increases as the temperature is raised higher than 150° C. It is considered that this is because the generation of oxygen radicals was promoted by heating the ozone gas as described above with reference to FIG. 11.

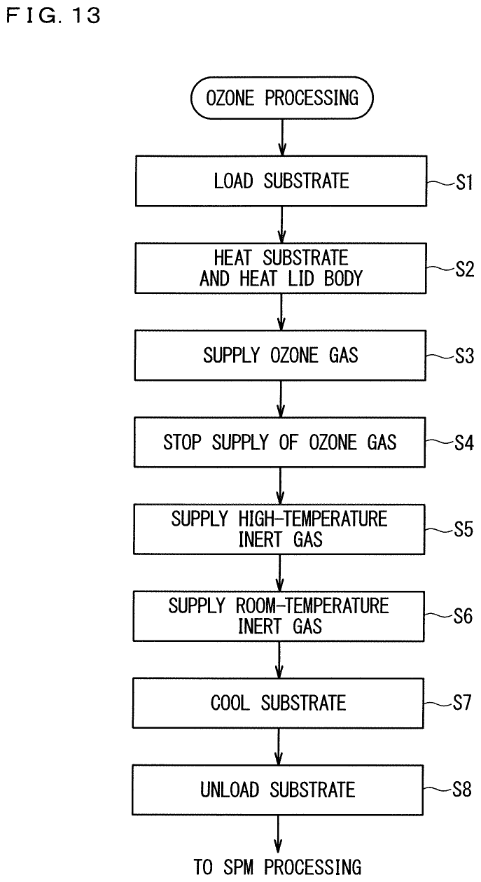

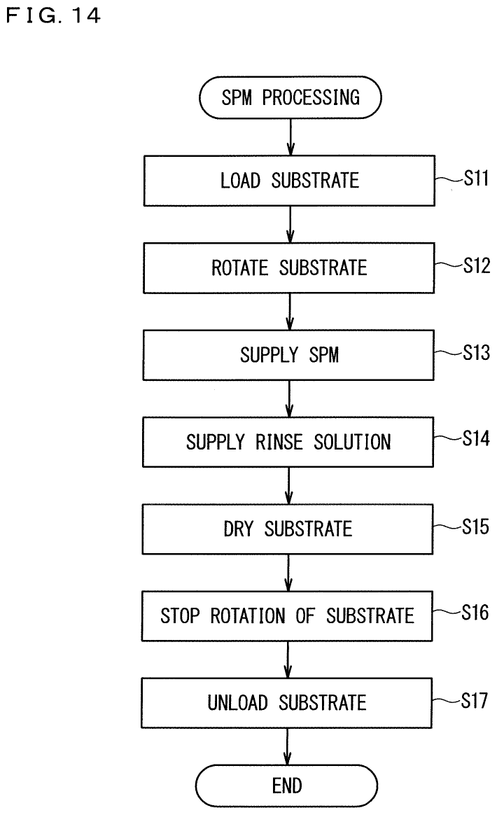

FIGS. 13 and 14 are flowcharts for describing a specific flow of the substrate processing by the substrate processing apparatus 1. FIG. 13 shows details of the ozone processing (hardened film removal processing), and FIG. 14 shows details of the SPM processing performed thereafter. The ozone processing and the SPM processing are realized by the control apparatus 3 controlling corresponding control targets.

The substrate W (FIG. 1) to be processed, in other words, the substrate W provided with the resist film 100 (FIG. 8), is taken out by the indexer robot IR and transferred to the shuttle SH. The center robot CR receives the substrate W and loads the substrate W into the dry chamber 4. The substrate W loaded into the dry chamber 4 is passed to the lift pins 38 of the thermal processing unit 8 by the in-chamber transport mechanism 6.

In step S1, the substrate W is placed on the placement surface 30a of the hot plate 30 by lowering the lift pins 38. When the lid 240 is lowered, the substrate W is covered with the lid 240 via the space SP and sealed in the thermal processing chamber 34.

In step S2, the placement surface 30a of the substrate placing unit 30 on which the substrate W is placed is heated to a first temperature (hereinafter, referred to as a substrate temperature) by the first heater 33. Consequently, after a certain waiting time has elapsed, the substrate W is substantially heated to a desired substrate temperature. This waiting time is, for example, about several minutes and usually does not need to exceed ten minutes. While the placement surface 30a is heated as described above, the lid 240 is heated to a second temperature (hereinafter, also referred to as a lid temperature) by the second heater 300. At this time, it is preferable that the straightening plate 47 be also heated to the lid temperature through smooth thermal coupling of the straightening plate 47 to the lid 240. The lid temperature is set to be higher than the substrate temperature. Preferably, the substrate temperature is 150° C. or lower and the lid temperature is higher than 150° C. In addition, preferably, the substrate temperature is 100° C. or higher. In addition, preferably, the lid temperature is 200° C. or lower. The substrate temperature may be controlled referring to a thermometer attached to the faceplate 31 constituting the placement surface 30a. In addition, the lid temperature may be controlled referring to a thermometer attached to the outer surface 242 of the lid 240.

In step S3, an ozone gas supplying step of introducing the ozone gas into the thermal processing chamber 34 is executed while the heating in step S2 is performed. That is, when the ozone gas valve 56 is opened, the ozone gas is introduced from the through-hole 248, and the internal atmosphere of the thermal processing chamber 34 is exhausted from the exhaust port 41. Consequently, the ozone gas is also introduced into the space SP through the through-hole 248. The ozone concentration of the ozone gas may be, for example, 100 g/cm³ to 200 g/cm³. In addition, a supply flow rate of the ozone gas may be about 5 liters/minute to 20 liters/minute.

As described above, air in the space SP of the thermal processing chamber 34 is replaced with the ozone gas, and the ozone gas reaches the substrate W (more specifically, the front surface of the hardened film 101). At least a part of ozone in the ozone gas is thermally decomposed before reaching the substrate W. Heating of the ozone gas for causing the thermal decomposition is substantially performed by the heating performed from the lid 240 having the lid temperature and is mainly performed through the space SP1. At least a part of the hardened film 101 is removed by the action of oxygen radicals generated by the thermal decomposition. This processing is performed, for example, for about 30 seconds. In this processing, since a lifespan of the oxygen radical is relatively short, it is not preferable that the thermal decomposition of ozone occur at too early a timing. In order to avoid this occurrence, the temperature of the ozone gas is preferably lower than 150° C. and more preferably lower than 100° C. until the ozone gas reaches the through-hole 248.

When a process of removing the hardened film 101 by oxygen radicals ends, the control apparatus 3 closes the ozone gas valve 56 to stop the supply of the ozone gas (step S4) and, instead, opens the high-temperature inert gas valve 64. Consequently, a high-temperature inert gas is introduced into the thermal processing chamber 34 from the gas introducing port, and a high-temperature inert gas supplying step is executed (step S5). The high-temperature inert gas is supplied into the thermal processing chamber 34 while maintaining a temperature of 150° C. or higher (for example, 170° C.). Consequently, it is possible to sufficiently promote detoxification of the ozone gas even in a case where there is a position which has a relatively low temperature and at which the ozone gas is likely to stay in the thermal processing chamber 34. By supplying the high-temperature inert gas to the staying position, the staying ozone gas is thermally decomposed and quickly detoxified. The supply of the high-temperature inert gas is performed, for example, for about ten seconds.

Next, the control apparatus 3 closes the high-temperature inert gas valve 64 and, instead, opens the room-temperature inert gas valve 59. Consequently, a room-temperature inert gas is introduced into the thermal processing chamber 34 from the through-hole 248, and a room-temperature inert gas supplying step (step S6) is executed. Consequently, the atmosphere inside the thermal processing chamber 34 is replaced with the room-temperature inert gas. As a result, the thermal processing chamber 34 is cooled. The supply of the room-temperature inert gas may be performed, for example, for 30 seconds or less. Thereafter, the control apparatus 3 closes the room-temperature inert gas valve 59.

Note that step S5 (high-temperature inert gas supplying step) described above may be omitted, and in that case, a configuration for step S5 in the substrate processing apparatus 1 can also be omitted. In the present embodiment, since the lid 240 is directly heated by the second heater 300 as shown in FIG. 3, the thermal decomposition of ozone in the vicinity of the lid 240 is promoted. Since this thermal decomposition contributes to detoxification of the ozone gas, an adverse effect caused by omitting step S5 is small as compared with a case where the lid 240 is not directly heated. In particular, in the present embodiment, since the temperature of the lid 240 is increased, thermal decomposition for detoxification can be easily promoted particularly at a position where gas is likely to stay in the thermal processing chamber 34, such as a circumferential position of the cylindrical portion 246 of the lid 240. Even though step S5 is omitted, ozone can be sufficiently removed by performing step S6 for about three minutes or more, for example.

Next, the control apparatus 3 causes the lid 240 to retract upward to open the thermal processing chamber 34. Thereafter, the lift pins 38 push up the substrate W, and the pushed-up substrate W is transported to the cooling unit 7 by the in-chamber transport mechanism 6 and passed to the lift pins 22. Then, as the lift pins 22 is lowered, the substrate W is placed on the cool plate 20 and cooled (step S7). Consequently, the substrate W is cooled to about room temperature. After a substrate cooling process, the lift pins 22 push up the substrate W, and the substrate W is unloaded out of the dry chamber 4 by the center robot CR (step S8).

The center robot CR loads the substrate W into the wet chamber 9 for the SPM processing (wet processing step) (step S11). Specifically, the control apparatus 3 controls the center robot CR (see FIG. 1) holding the substrate W to cause the hand H to enter the inside of the wet chamber 9, and thereby the substrate W is placed on the spin chuck 70 in a state where the front surface (the front surface on which the resist is formed) of the substrate W is directed upward. Thereafter, the control apparatus 3 causes the spin motor 77 to start rotating the substrate W (step S12). A rotation speed of the substrate W is increased to a predetermined processing rotation speed (within a range of 100 rpm to 500 rpm, for example, about 300 rpm) and is maintained at the processing rotation speed. When the rotation speed of the substrate W reaches the processing rotation speed, the control apparatus 3 performs an SPM processing step (step S13) of supplying the SPM, which is a processing liquid containing sulfuric acid, to the substrate W.

Specifically, the control apparatus 3 controls the nozzle moving unit 87 to move the SPM nozzle 85 from the home position to the processing position. Consequently, the SPM nozzle 85 is disposed above the substrate W. After the SPM nozzle 85 is disposed above the substrate W, the control apparatus 3 opens the sulfuric acid valve 90 and the hydrogen peroxide solution valve 96. Consequently, the hydrogen peroxide solution flowing through the hydrogen peroxide solution pipe 95 and the sulfuric acid flowing through the sulfuric acid pipe 89 are supplied to the SPM nozzle 85. Consequently, the sulfuric acid and the hydrogen peroxide solution are mixed in the mixing chamber of the SPM nozzle 85, and an SPM having a high temperature (for example, 160° C.) is generated (generation step). The SPM having the high temperature is ejected from an ejection port of the SPM nozzle 85 and lands on the top surface of the substrate W (supplying step). The control apparatus 3 controls the nozzle moving unit 87 to move the liquid landing position of the SPM with respect to the top surface of the substrate W between the central portion and the circumferential portion. The SPM ejected from the SPM nozzle 85 lands on the top surface of the substrate W rotating at the processing rotation speed (for example, 300 rpm) and then flows outward along the top surface of the substrate W by centrifugal force. Therefore, the SPM is supplied to the entire top surface of the substrate W, and a liquid film of the SPM covering the entire top surface of the substrate W is formed on the substrate W. This processing is performed for a predetermined SPM processing time (for example, about 30 seconds), and thereby a resist on the front surface of the substrate W is removed by the SPM. When the predetermined SPM processing time has elapsed from the start of the ejection of the SPM, the SPM processing step (step S13) ends. Specifically, the control apparatus 3 closes the hydrogen peroxide solution valve 96 and the sulfuric acid valve 90. In addition, the control apparatus 3 controls the nozzle moving unit 87 to move the SPM nozzle 85 from the processing position to the home position. Consequently, the SPM nozzle 85 retracts from above the substrate W.

Next, a rinse solution supplying step (step S14) of supplying the rinse solution to the substrate W is performed. Specifically, the control apparatus 3 opens the rinse solution valve 82 to eject the rinse solution from the rinse solution nozzle 80 toward the central portion of the top surface of the substrate W. The rinse solution ejected from the rinse solution nozzle 80 replaces the SPM on the substrate W and washes the SPM away. When a predetermined rinse solution supply time elapses after the rinse solution valve 82 is opened, the control apparatus 3 closes the rinse solution valve 82 and stops ejection of the rinse solution from the rinse solution nozzle 80.

Next, a drying step (step S15) of drying the substrate W is performed. Specifically, the control apparatus 3 causes the substrate W to accelerate to a drying rotation speed (for example, thousands of rpm) by controlling the spin motor 77 and rotates the substrate W at the drying rotation speed. Consequently, a large centrifugal force is applied to a liquid on the substrate W, and the liquid adhering to the substrate W is shaken off around the substrate W. In this manner, the liquid is removed from the substrate W, and the substrate W is dried. When a predetermined time has elapsed since the start of the high-speed rotation of the substrate W, the control apparatus 3 controls the spin motor 77 to stop the rotation of the substrate W by the spin chuck 70 (step S16).

Next, an unloading step of unloading the substrate W from the wet chamber 9 is performed (step S17). Specifically, the control apparatus 3 causes the hand H of the center robot CR to enter the inside of the wet chamber 9 to hold the substrate W on the spin chuck 70 and then causes the hand H to retract from the wet chamber 9. Consequently, the processed substrate W is unloaded out of the chamber. The center robot CR transfers the substrate W to the shuttle SH. The shuttle SH transports the substrate W toward the indexer robot IR. The indexer robot IR receives the processed substrate W from the shuttle SH and accommodates the substrate W in a carrier C.

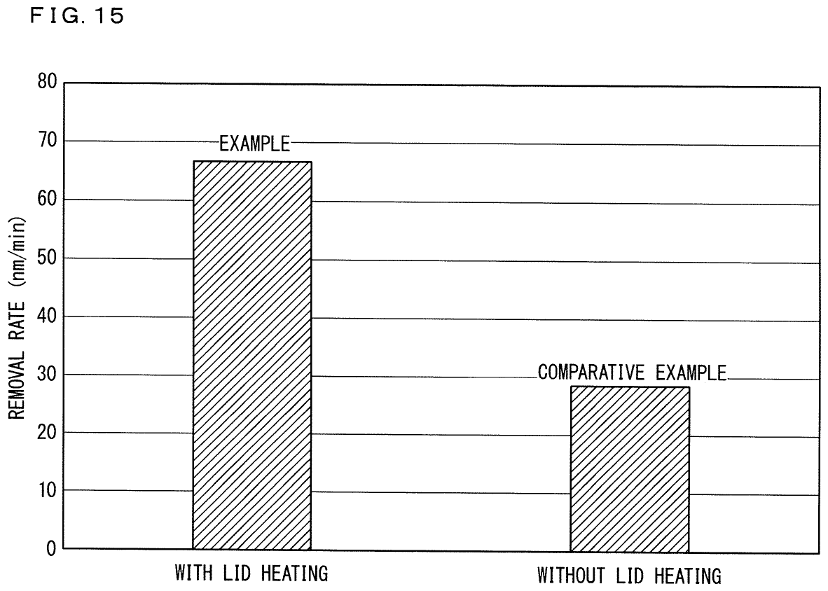

FIG. 15 is a graph showing experimental results of a removal rate of the resist film 100 in an example in which the lid 240 is heated to 180° C. and a comparative example in which the lid 240 is not heated. Incidentally, the substrate temperature was 150° C. in common in the example and the comparative example. As can be known from this result, the removal rate remarkably increased by heating the lid 240.

According to the present embodiment, the ozone gas is introduced into the space SP through the through-hole 248 of the lid 240 while the substrate W is heated to the first temperature (substrate temperature) and the lid 240 is heated to the lid temperature (second temperature higher than the first temperature). Since the substrate temperature is lower than the lid temperature, the temperature of the substrate W is suppressed as compared with the case where the substrate temperature is equal to or higher than the lid temperature. Consequently, it is possible to suppress the progress of oxidation of the substrate W when the resist film 100 on the substrate W is removed by the substrate processing method. For example, in a case where the substrate W is a silicon substrate, unintended formation of a silicon oxide film can be suppressed, and in a case where the substrate W has an inorganic film on the front surface, unintended oxidation of the inorganic film can be suppressed. In addition, since the lid temperature is higher than the substrate temperature, the temperature of the gas in the space SP on the substrate W is higher than that in a case where the lid temperature is equal to or lower than the substrate temperature. Consequently, this promotes generation of radicals by thermal decomposition of ozone in the gas. Accordingly, the resist film 100 on the substrate W can be efficiently removed. From the description provided above, it is possible to suppress the progress of oxidation of the substrate W while efficiently removing the resist film 100 from the substrate W.

In a case where the substrate temperature is 150° C. or lower, the progress of oxidation of the substrate W can be more sufficiently suppressed. In addition, popping of the resist film 100 due to excessive heating of the resist film 100 can be prevented. In a case where the lid temperature is higher than 150° C., the generation of radicals by the thermal decomposition of ozone in the gas is more sufficiently promoted.

In a case where the substrate temperature is 100° C. or higher, the temperature of the resist film 100 is thereby increased. Consequently, the resist film 100 can be more efficiently removed.

In a case where the lid temperature is 200° C. or lower, it is possible to prevent the gas pipe 49 for supplying the gas to the through-hole 248 of the lid 240 from being excessively heated by heat conduction from the lid 240. Consequently, the thermal decomposition of ozone in an upstream part of the gas pipe 49 is suppressed. Accordingly, it is possible to suppress a decrease in processing efficiency due to deactivation of the radicals before the radicals reach the substrate W.

In a case where a region having thermal conductivity lower than that of the gas pipe 49, such as the gap 310 (FIG. 3) or the heat insulating member 320 (FIG. 4), is interposed between the second heater 300 and the gas pipe 49, a temperature rise of the gas pipe 49 due to the heat from the second heater 300 is suppressed. Consequently, the thermal decomposition of ozone in an upstream part of the gas pipe 49 is suppressed. Accordingly, it is possible to suppress a decrease in processing efficiency due to deactivation of the radicals before the radicals reach the substrate W.

After the hardened film 101 (FIG. 8) is removed by the ozone processing described above, the wet processing step (FIG. 9) of supplying the high-temperature SPM to the front surface of the substrate W is executed. Consequently, the hardened film 101 (FIG. 8) having a relatively low removal rate by the SPM processing is removed in advance before the wet processing step is started. Therefore, since the time of the SPM processing is shortened, productivity is improved. Additionally, the consumption of the SPM, particularly the consumption of sulfuric acid as a raw material thereof, can be reduced. Consequently, the environmental load can be reduced.

As described above, one embodiment of the present invention has been described above, the present invention can be further implemented in other embodiments.

For example, in the above-described embodiment, an example has been described in which the dry processing for performing the ozone processing and the wet processing for supplying the SPM are performed by separate processing units (that is, separate chambers). However, the ozone processing and the wet processing for supplying the SPM may be performed in the same processing unit (in the same chamber). However, in that case, since it is necessary to adjust an environment in the chamber at the time of switching between the dry processing (ozone processing) and the wet processing, it is easier to efficiently perform the substrate processing by performing the dry processing and the wet processing in separate chambers.

In addition, in the above-described embodiment, the SPM is provided as an example of a resist peeling solution containing sulfuric acid, but as other examples, a sulfuric acid ozone solution obtained by mixing ozone in sulfuric acid, a hydrofluoric acid/sulfuric acid/hydrogen peroxide mixture obtained by adding hydrofluoric acid to a sulfuric acid/hydrogen peroxide solution, or a simple sulfuric acid aqueous solution can be provided.

In addition, various design changes can be made within the scope of the matters described in the claims.

### EXPLANATION OF REFERENCE SIGNS

1: substrate processing apparatus
2D: dry processing unit
2W: wet processing unit
3: control apparatus
8, 8M: thermal processing unit
30: hot plate (substrate placing unit)
30a: placement surface
31: faceplate
32: under plate
33: first heater
34: thermal processing chamber
35: chamber body
47: straightening plate
48: through-hole
49: gas pipe
55: ozone gas generator (gas supply unit)
100: resist film
240: lid
241: inner surface
242: outer surface
245: plate portion
248: through-hole
300: second heater
320: heat insulating member
SP: space
W: substrate

1. A substrate processing method for removing an organic film from a substrate by using a substrate processing apparatus including a substrate placing unit having a placement surface on which the substrate is placed, and a lid that covers the substrate placed on the placement surface with a space interposed between the lid and the substrate, has an inner surface facing the space and an outer surface opposite to the inner surface, and has a through-hole connecting the inner surface and the outer surface, the substrate processing method comprising the steps of:
a) placing the substrate having the organic film on the placement surface of the substrate placing unit such that the substrate is covered with the lid with the space interposed between the lid and the substrate;
b) heating the lid to a second temperature higher than a first temperature while heating the placement surface of the substrate placing unit on which the substrate is placed to the first temperature; and
c) introducing a gas containing ozone into the space through the through-hole of the lid while performing the step of b).

2. The substrate processing method according to claim 1, wherein the first temperature is 150° C. or lower, and the second temperature is higher than 150° C.

3. The substrate processing method according to claim 2, wherein the first temperature is 100° C. or higher.

4. The substrate processing method according to claim 2, wherein the second temperature is 200° C. or lower.

5. A substrate processing apparatus for removing an organic film from a substrate, the substrate processing apparatus comprising:
a substrate placing unit that has a placement surface on which the substrate is to be placed and is equipped with a first heater for heating the placement surface;
a lid that covers the substrate placed on the placement surface of the substrate placing unit with a space interposed between the lid and the substrate, has an inner surface facing the space and an outer surface opposite to the inner surface, and has a through-hole connecting the inner surface and the outer surface;
a second heater provided on the outer surface of the lid to heat the lid;
a gas pipe that projects from the outer surface of the lid and supplies a gas to the through-hole of the lid;
a gas supply unit that supplies a gas containing ozone to the gas pipe; and
a controller that controls the first heater and the second heater,
wherein the controller controls the first heater so that the placement surface of the substrate placing unit on which the substrate is placed is heated to a first temperature and controls the second heater so that the lid is heated to a second temperature higher than the first temperature.

6. The substrate processing apparatus according to claim 5, wherein a region having thermal conductivity lower than thermal conductivity of the gas pipe is interposed between the second heater and the gas pipe.

7. The substrate processing apparatus according to claim 6, wherein the region includes a gap.

8. The substrate processing apparatus according to claim 6, wherein the region includes a member having thermal conductivity lower than thermal conductivity of the gas pipe.
